(19) United States
(12) Patent Application Publication
(10) Pub. No.: US 2020/0082874 A1
(43) Pub. Date: Mar. 12, 2020

(54) SEMICONDUCTOR MEMORY DEVICE

(71) Applicants: Kabushiki Kaisha Toshiba, Tokyo (JP); Toshiba Electronic Devices & Storage Corporation, Tokyo (JP)

(72) Inventor: Toshiaki Dozaka, Yokohama Kanagawa (JP)

(21) Appl. No.: 16/294,169

(22) Filed: Mar. 6, 2019

(30) Foreign Application Priority Data
Sep. 11, 2018 (JP) 2018-169564

(51) Int. Cl. G11C 11/417; G11C 11/419

(52) U.S. Cl. CPC G11C 11/417; G11C 11/419

(57) ABSTRACT

According to one embodiment, a semiconductor memory device that includes a first bitline, a second bitline, a clock generator and a timing control circuit. The clock generator is configured to generate a first clock signal that rises in synchronization with a basic clock signal and determine a timing in which the first bitline and the second bitline are connected. The timing control circuit is configured to generate a control signal that controls a timing of a read operation in synchronization with the first clock signal, an apparatus includes

### CROSS-REFERENCE TO RELATED APPLICATIONS

This application is based upon and claims the benefit of priority from the Japanese Patent Application No. 2018-169564, filed Sep. 11, 2018, the entire contents of which are incorporated herein by reference.

### FIELD

Embodiments described herein relate generally to a semiconductor memory device that is applied to a static RAM.

### BACKGROUND

As existing semiconductor memory devices, a Static Random Access Memory (SRAM) has been well known. For example, a SRAM is applied to a cache memory because of the capability of high-speed access. Types of a SRAM include, in particular, a Charge-Sharing type SRAM (CS-SRAM) that is capable of reducing power consumption.

A CS-SRAM has difficulty controlling an operation timing, which may cause a deterioration in operation speed. To suppress a deterioration in operation speed, it is effective to realize optimum operation timing control for a CS-SRAM.

### BRIEF DESCRIPTION OF THE DRAWINGS

FIG. 1 is a diagram showing a configuration of a SRAM according to an embodiment;

FIG. 2 is a diagram showing an example of a partial configuration of the SRAM according to the embodiment;

FIG. 3 is a timing chart for illustrating a read operation of the SRAM according to the embodiment;

FIG. 4 is a diagram for illustrating an example of a clock generator according to the embodiment; and

FIG. 5 is a diagram for illustrating an example of the clock generator according to the embodiment.

### DETAILED DESCRIPTION

In general, according to one embodiment, a semiconductor memory device that includes a first bitline, a second bitline, a clock generator and a timing control circuit. The clock generator is configured to generate a first clock signal that rises in synchronization with a basic clock signal and determines a timing in which the first bitline and the second bitline are connected. The timing control circuit is configured to generate a control signal that controls a timing of a read operation in synchronization with the first clock signal.

Various embodiments will be described hereinafter with reference to the accompanying drawings.

### [Configuration of SRAM]

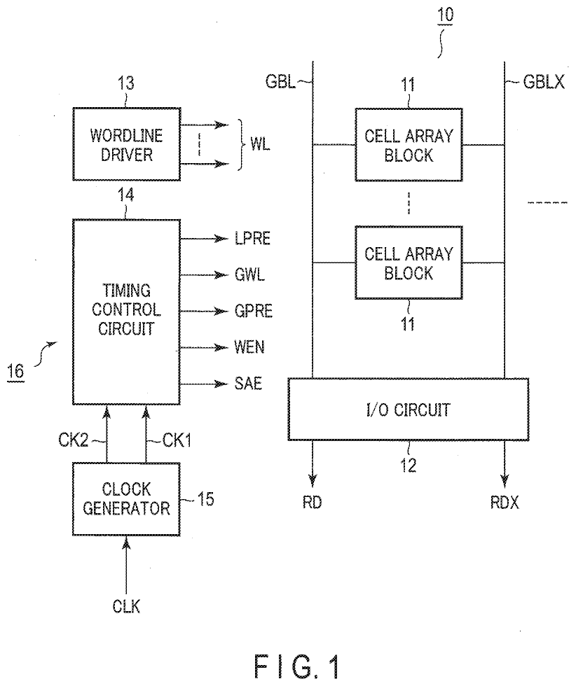

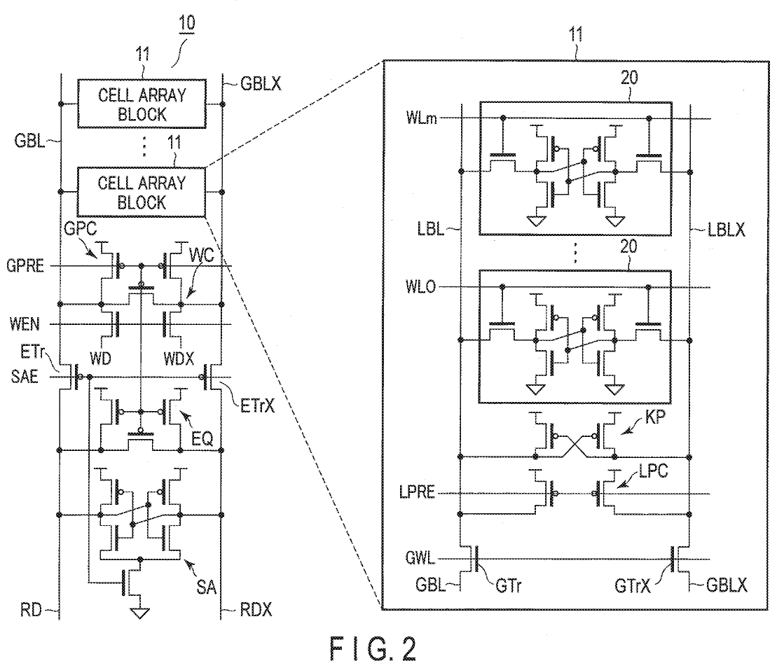

FIG. 1 is a diagram showing a configuration of a SRAM according to the present embodiment. FIG. 2 is a diagram showing an example of a partial configuration of the SRAM.

As shown in FIG. 1, a SRAM 10 according to the present embodiment includes a plurality of cell array blocks (hereinafter, occasionally referred to as “CAB or CABs”) 11 arranged in a column direction between global bitlines GBL/GBLX placed in parallel. The SRAM 10 further includes an I/O (input/output) circuit 12 arranged between the global bitlines GBL/GBLX. In the present embodiment, a configuration of one of columns in the SRAM 10 is described, while a description is omitted with respect to a configuration of the rest of the columns, which is similar to the one shown in FIG. 1.

The SRAM 10 further includes a controller 16 that generates a variety of control signals (timing signals) for controlling an internal operation timing for each of the cell array blocks 11 and the I/O (input/output) circuit 12.

The controller 16 includes a wordline driver 13, a timing control circuit 14, and a clock generator 15. The wordline driver 13 applies a selection signal (driving voltage) to wordlines WL. The timing control circuit 14 generates a local pre-charge signal LPRE, a global connection signal GWL, a global pre-charge signal GPRE, a write enable signal WEN, and a sense amplifier drive signal SAE of a sense amplifier (SA), as described later. In the present embodiment, the clock generator 15 generates a first clock CK1 and a second clock CK2 based on a basic clock CLK, as a synchronization clock for generating each control signal, as described later, and supplies the first and second clocks CK1 and CK2 to the timing control circuit 14.

Next, as shown in FIG. 2, each of the cell array blocks 11 has an internal configuration including local bitlines LBL/LBLX placed in parallel, a plurality of memory cells (bit cells)20 connected between the local bitlines LBL/LBLX, a local pre-charge circuit LPC, a keeper circuit KP, and global connection transistors GTr/GTrX.

That is, the SRAM 10 according to the present embodiment is a CS-SRAM with a hierarchical bitline structure in which the local bitlines LBL/LBLX that are divided short are connected to the long global bitlines GBL/GBLX through the global connection transistors GTr/GTrX. Charge-Sharing (CS) will be described later.

Referring to FIG. 2, a specific configuration of the SRAM 10 according to the present embodiment is described. As shown in FIG. 2, each of the memory cells 20 has a known configuration including a flip-flop and two transfer transistors. Each of the transfer transistors has a gate connected to a wordline WL (WLm-WL0), and is turned to an ON state when a selection signal is applied to the wordline WL. Accordingly, each of the memory cells 20 is connected to the local bitlines LBL/LBLX.

The local pre-charge circuit LPC operates by input of the local pre-charge signal LPRE (L level) described above, and pre-charges the local bitlines LBL/LBLX (to an H level). The keeper circuit KP maintains the pre-charged local bitlines LBL/LBLX at an H level.

The global connection transistors GTr/GTrX are transistors for connecting the local bitlines LBL/LBLX to the global bitlines GBL/GBLX. With the global connection signal GWL at an H level, the global connection transistors GTr/GTrX are turned to an ON state, and connects the local bitlines LBL/LBLX to the global bitlines GBL/GBLX. On the other hand, with the global connection signal GWL at an L level, the global connection transistors GTr/GTrX are turned to an OFF state, and cuts off the connection described above.

The SRAM 10 according to the present embodiment is configured in a manner so that each of the cell array blocks 11 and the I/O (input/output) circuit 12 are arranged between the global bitlines GBL/GBLX, as described above. The I/O circuit 12 includes a global pre-charge circuit GPC, a write circuit WC, connection transistors ETr/ETrX, an equalizer EQ, and a sense amplifier SA.

The global pre-charge circuit GPC operates by input of the global pre-charge signal GPRE (L level), and pre-charges the global bitlines GBL/GBLX (to an H level). The write circuit WC operates by the write enable signal WEN (H level) and turns the global bitlines GBL/GBLX to a state (H/L level) in accordance with write data. In the present embodiment, a read operation of the SRAM 10 is described, while a description of a write operation is omitted.

With a sense amplifier driving signal SAE at an L level, the connection transistors ETr/ETrX are turned to an OFF state, and connects the global bitlines GBL/GBLX to data-outputting extension bitlines RD/RDX. On the other hand, with the sense amplifier driving signal SAE at an H level, the connection transistors ETr/ETrX are turned to an OFF state, and cut off the connection described above.

The equalizer EQ operates by input of the global pre-charge signal GPRE (L level), and short-circuits between the global bitlines GBL/GBLX, thereby turning them to an H level. With the global pre-charge signal GPRE at an H level, the equalizer EQ is turned to an OFF state. The sense amplifier SA is turned to an ON state with the sense amplifier driving signal SAE at an H level, and is turned to an OFF state with the sense amplifier driving signal SAE at an L level. While in an ON state, the sense amplifier SA amplifies one of the extension bitlines RD/RDX, whichever is greater in voltage, to an H level, and amplifies the other of the extension bitline RD/RDX, whichever is smaller in voltage, to an L level.

### Operation and Advantageous Effects

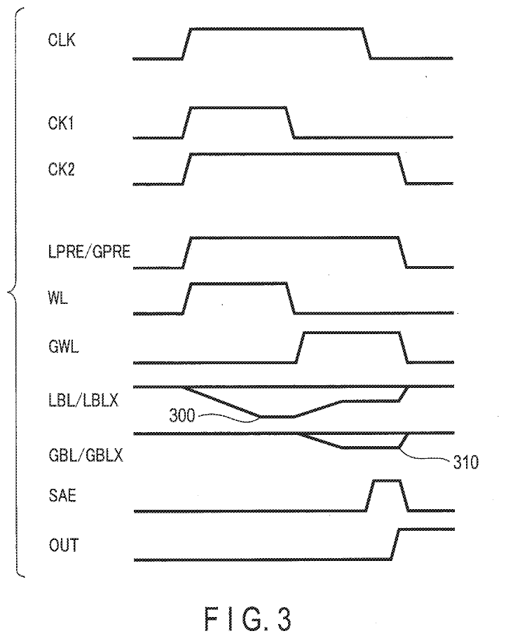

Next, the operation and advantageous effects of the SRAM according to the present embodiment will be described. In the present embodiment, a read operation of the SRAM 10 is described. FIG. 3 is a timing chart for illustrating a read operation of the SRAM 10 according to the present embodiment.

The SRAM 10 according to the present embodiment is a CS-SRAM with a hierarchical bitline structure including the local bitlines LBL/LBLX and the global bitlines GBL/GBLX, as described above.

Herein, during a read operation, the write circuit WC is in an OFF state. Described as an example of the read operation according to the present embodiment is an operation to read stored data from the memory cells 20 connected to, for example, the wordline WL0 (hereinafter, simply referred to as “wordline WL”), as shown in FIG. 2. In each of the memory cells 20, in accordance with an operation to read stored data, as described later, a node connected to the local bitline LBL is turned to an L level while a node connected to the local bitline LBLX is turned to an H level.

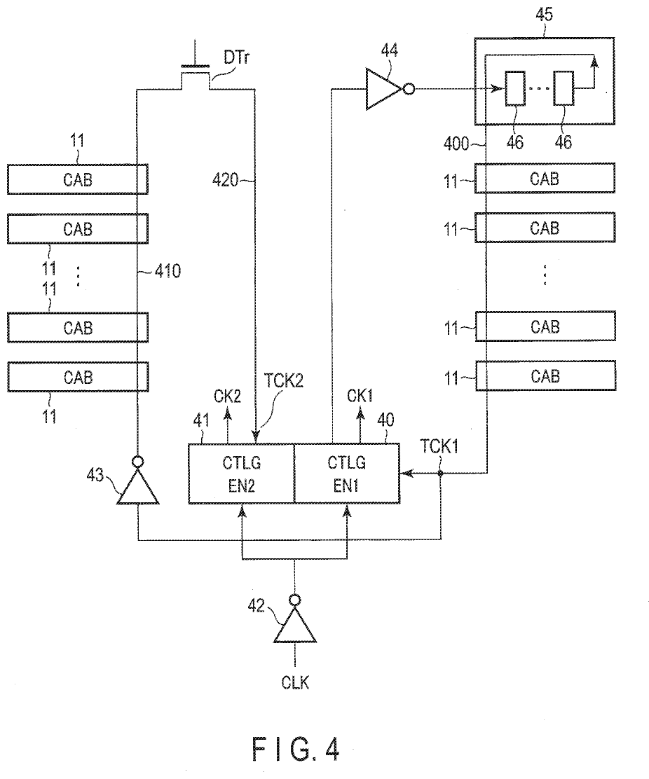

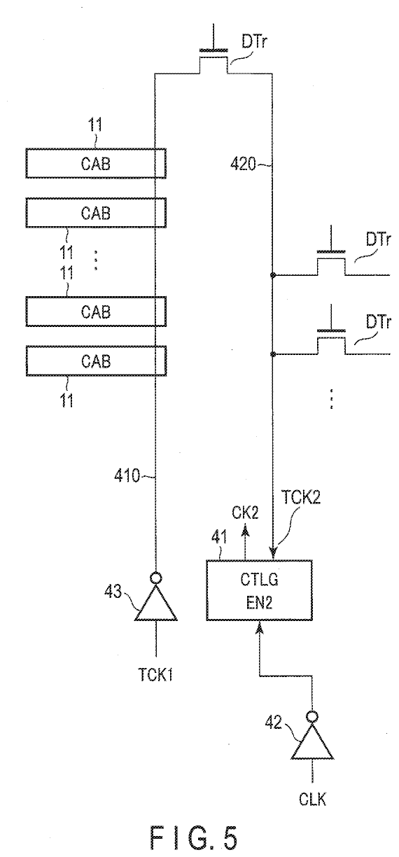

Generally, the read operation of the SRAM 10 is executed in synchronization with a rise of the basic clock CLK. In the present embodiment, as shown in FIG. 1 and FIG. 3, the clock generator 15 generates the first clock CK1 and the second clock CK2 as internal synchronization clocks from the basic clock CLK. The basic clock CLK is external clock to the controller 16. The configuration of the clock generator 15 will be described later with reference to FIG. 4 and FIG. 5.

The timing control circuit 14 generates each control signal for controlling the operation timing of the SRAM 10, in synchronization with the first clock CK1 and the second clock CK2. As shown in FIG. 3, the first clock CK1 and the second clock CK2 rise in synchronization with a rise of the basic clock CLK.

At this timing, both the local pre-charge signal LPRE (L level has higher significance) and the global pre-charge GPRE (L level has higher significance) change to an H level. Therefore, both the local pre-charge circuit LPC and the global pre-charge circuit GPC are in an OFF state. Note that in the initial state, the local bitlines LBL/LBLX and the global bitlines GBL/GBLX are at an H level.

During the read operation, a selection signal (WL) of an H level is applied from the wordline driver 13 to the wordline WL (WLm). This brings a state in which the memory cell 20 is connected to the local bitlines LBL/LBLX.

On the other hand, each of the global connection signal GWL (H level has higher significance) and the sense amplifier driving signal SAE (H level has higher significance) is at an L level. Therefore, the global connection transistors GTr/GTrX are in an OFF state, and connection between the local bitlines LBL/LBLX and the global bitlines GBL/GBLX is cut off. Furthermore, the sense amplifier SA is in an OFF state since the sense amplifier driving signal SAE is at an L level.

In the memory cell 20, the nodes are connected to the local bitlines LBL/LBLX, respectively, so that a level of one local bitline LBL changes to an L level, in accordance with stored data (300). In this state, a level of the other local bitline LBLX is at an H level.

Thereafter, the selection signal (WL) with respect to the wordline WL changes to an L level, and when the global connection signal GWL changes to an H level in synchronization with this change, the global connection transistors GTr/GTrX are turned to an ON state. Thus, the local bitline LBL at an L level connects to the global bitline GBL of an H level. In addition, since the sense amplifier driving signal SAE has an L level, the connection transistors ETr/ETrX are turned to an ON state, thereby connecting the global bitlines GBL/GBLX to the extension bitlines RD/RDX.

This state causes transfer of charges from the global bitlines GBL/GBLX and the extension bitlines RD/RDX to the local bitlines LBL/LBLX, thereby generating charge-sharing. With this charge-sharing, a voltage of the global bitline GBL at an H level decreases by a capacity of the local bitline LBL at an L level (310). In this case, since the global bitline GBL and the extension bitline RD are connected to each other, a voltage of the extension bitline RD decreases, too. At the same time, a voltage of the local bitline LBL at an L level increases because of this charge-sharing.

When the sense amplifier driving signal SAE changes to an H level after voltages of the global bitline GBL and the extension bitline RD decrease, the connection transistors ETr/ETrX are turned to an OFF state, thereby cutting off connection between the global bitlines GBL/GBLX and the extension bitlines RD/RDLX. In this case, a connection state between the local bitlines LBL/LBLX and the global bitlines GBL/GBLX is maintained. Accordingly, at this point, a voltage of each of the local bitlines LBL/LBLX and the global bitlines GBL/GBLX is maintained.

When the sense amplifier driving signal SAE changes to an H level, the sense amplifier SA is turned to an ON state. This changes a voltage of the extension bitline RD to an L level, while maintaining a voltage of the extension bitline RDX at an H level. The SRAM 10 outputs read data in accordance with a difference in voltage level between the extension bitlines RD/RDX (OUT). When the sense amplifier driving signal SAE changes to an L level, each control signal reverts to the initial state described above.

As described, the SRAM 10 according to the present embodiment is a CS-SRAM with a hierarchical bitline structure, thereby making it possible to reduce power consumption especially in the read operation Specifically, the local bitlines LBL/LBLX are connected to the global bitlines GBL/GBLX in accordance with a change of an H level of the global connection signal GWL. Accordingly, the global bitlines GBL/GBLX change to a level state corresponding to data of the memory cell 20 connected to the local bitlines LBL/LBLX.

Herein, as shown in FIG. 3, when the selection signal (WL) at an H level is applied from the wordline driver 13 to the wordline WL (WLm), a level of one local bitline LBL changes to an L level, in accordance with stored data (300). A level of the other local bitline LBLX is at an H level. Thereafter, when the selection signal (WL) with respect to the wordline WL changes to an L level, the memory cell 20 is disconnected from the local bitlines LBL/LBLX. Accordingly, a level of the local bitline LBL is maintained at an L level.

Furthermore, when the global connection signal GWL changes to an H level, the global connection transistors GTr/GTrX are turned to an ON state. This connects the local bitline LBL at an L level to the global bitline GBL at an H level, thereby generating charging-share described above. Accordingly, a voltage of the global bitline GBL at an H level decreases by a capacity of the local bitline LBL at an L level (310). Along with this, a voltage of the local bitline LBL at an L level increases because of this charge-sharing.

By this read operation, 1-bit data can be read from the memory cell 20. At this point, because of generation of charge-sharing, the global bitline GBL consumes no power. As a result, power consumption during the read operation can be suppressed.

In this respect, the CS-SRAM is required to optimally control a timing at which a level of the local bitline LBL changes to an L level and maintains it, and a timing from generation to ending of charge-sharing. The timing from generation to ending of charge-sharing indicates a timing from a point when a voltage of the global bitline GBL at an H level decreases by a capacity of the local bitline LBL at an L level to a point when a voltage of the local bitline LBL at an L level increases because of this charge-sharing. If these timings are not optimum, there is a possibility that the speed of the read operation is destabilized and is therefore deteriorated.

Thus, according to the present embodiment, the clock generator 15 included in the controller 16 generates the first clock CK1 and the second clock CK2 from the basic clock CLK of the SRAM 10. The timing control circuit 14 generates each control signal using the first clock CK1 and the second clock CK2, as internal synchronization clocks.

Specifically, as shown in FIG. 3, the first clock CK1 and the second clock CK2 rise in synchronization with a rise of the basic clock CLK. The timing control circuit 14 generates each control signal in synchronization with rises of the first and second clocks CK1 and CK2.

Herein, the first clock CK1 has a clock width (time from a rise point to a fall point) that determines a timing of terminating read of the local bitlines LBL/LBLX. That is, a clock width of the first clock CK1 corresponds to the timing at which a level of the local bitline LBL changes to an L level and maintains it. The timing control circuit 14 changes the global connection signal GWL to an H level in synchronization with a fall point of the first clock CK1.

Next, the second clock CK2 has a clock width that determines a timing from a rise point to ending of charging-share. That is, a clock width of the second clock CK2 corresponds to a timing from a rise point to a point when connection between the local bitlines LBL/LBLX and the global bitlines GBL/GBLX is cut off in accordance with a change of L level of the global connection signal GWL.

FIG. 4 and FIG. 5 are diagrams illustrating one example of the configuration of the clock generator 15 according to the present embodiment.

As shown in FIG. 4, the clock generator 15 according to the present embodiment includes a first control generator (CTLG) 40 that generates the first clock CK1 and a second control generator (CTLG) 41 that generates the second clock CK2. The first control generator 40 and the second control generator 41 receive the basic clock CLK which is input through a driver (inverter) 42, as an enable signal EN1 and an enable signal EN2, respectively.

The first control generator 40 outputs the enable signal EN1 corresponding to a rise of the first clock CK1 through a driver 44 to a delay circuit 45. The delay circuit 45 configures, for example, a circuit having a plurality of bit cells 46 connected in series, and inputs the enable signal EN1 and outputs it to a dummy bitline 400 connected to an output side. That is, the delay circuit 45 generates a timing that reflects characteristics (bitline pair capacity) of the bit cells 46.

The dummy bitline 400 is connected to at least one of bitlines (local bitlines LBL/LBLX) of two or more cell array blocks (CABs) 11, for example. The dummy bitline 400 transmits a timing control signal TCK1 that determines a fall timing of the first clock CK1, to the first control generator 40.

The above configuration enables the first control generator 40 to generate the first clock CK1 having a clock width that rises in synchronization with a rise of the basic clock signal CLK and falls in accordance with the timing control signal TCK1 that passes through a delay path using the dummy bitline 400, as shown in FIG. 3. Herein, the dummy bitline 400 can secure, for example, a delay of about 100 mV by a load of a single CAB, and a delay of about 800 mV by a load of eight CABs.

Therefore, the timing control circuit 14 can change the global connection signal GWL to an H level in synchronization with the first clock CK1 having a clock width corresponding to a timing from a rise point to a point at which a level of the local bitline LBL changes to an L level and maintains it.

Next, as shown in FIG. 4, the second control generator 41 inputs the basic clock CLK as the enable signal EN2 through the driver (inverter) 42, thereby generating the second clock CK2 that rises in synchronization with the basic clock CLK. The clock generator 15 according to the present embodiment outputs the timing control signal TCK1 that determines a fall timing of the first clock CK1, to a dummy bitline 410 through a driver 43.

The second control generator 41 generates the second clock CK2 having a clock width that falls in accordance with the timing control signal TCK2 to be transmitted through a dummy global bitline 420, as described later. Hereinafter, the method of generating the second clock CK2 will be described with reference to FIG. 5.

As shown in FIG. 5, the dummy bitline 410 is connected to at least one of bitlines (local bitlines LBL/LBLX) of two or more cell array blocks (CABs) 11, for example. Furthermore, the dummy bitline 410 is connected to the dummy global bitline 420 through a dummy transistor DTr having similar characteristics (such as a size) to those of the global connection transistors GTr/GTrX. The dummy transistor DTr is turned to an ON state in accordance with a change of an H level of the global connection signal GWL.

The dummy global bitline 420 has a metal layer and a width that are similar to those of the global bitlines GBL/GBLX. Furthermore, the dummy transistor DTr having similar characteristics (such as a size) to those of the global connection transistors GTr/GTrX is connected as a load transistor to the dummy global bitline 420.

The above configuration enables the second control generator 41 to generate the second clock CK2 having a clock width that rises in synchronization with a rise of the basic clock signal CLK and falls in accordance with the timing control signal TCK2 that is transmitted through the dummy global bitline 420, as shown in FIG. 3.

Herein, the timing control signal TCK2 determines a timing at which charge-sharing between the local bitline LBL and the global bitline GBL ends, in accordance with an input of the timing control signal TCK1. The timing control signal TCK1 determines a timing at which a level of the local bitline LBL changes to an L level and maintains it, as described above.

A delay time that follows transfer of charges between the local bitline LBL and the global bitline GBL corresponds to a timing at which a charge-sharing ends. In such a case, the timing control signal TCK2 is transmitted through the dummy global bitline 420 having a similar load to that of the global bitline GBL. Thus, the timing control signal TCK2 has delay characteristics including a similar variation of wiring.

As described above, a CS-SRAM with a hierarchical bitline structure to which the present embodiment is applied can reduce power consumption by suppressing power consumption during a read operation, and suppress deterioration in operation speed by realizing optimum timing control.

Specifically, the controller according to the present embodiment generates the first clock CK1 and the second clock CK2 from the basic clock CLK of the SRAM 10, and generates each control signal using them as internal synchronization clocks. The clock generator 15 can output the basic clock CLK as the second clock CK2. The first clock CK1 enables optimum control of a timing at which a level of the local bitline LBL changes to an L level and maintains it. The second clock CK2 enables optimum control of a timing from generation to ending of charge-sharing. This realizes a stabilized speed of a read operation, and as a result, suppresses deterioration in the speed of the read operation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device that includes a first bitline and a second bitline, comprising:
a clock generator configured to generate a first clock signal that rises in synchronization with a basic clock signal and determines a timing in which the first bitline and the second bitline are connected; and
a timing control circuit configured to generate a control signal that controls a timing of a read operation in synchronization with the first clock signal.

2. The semiconductor memory device of claim 1, wherein the clock generator is configured to generate a second clock signal that rises in synchronization with the basic clock signal and determines a timing in which the first bitline and the second bitline are disconnected, and the timing control circuit is configured to generate the control signal in synchronization with the first clock signal and the second clock signal.

3. The semiconductor memory device of claim 1, wherein the timing control circuit is configured to generate the control signal in synchronization with the first clock signal and the basic clock signal.

4. The semiconductor memory device of claim 1, wherein the semiconductor memory device is applied to a static random access memory (SRAM).

5. A semiconductor memory device that is applied to a static random access memory (SRAM) with a hierarchical bitline structure including a first bitline and a second bitline, the semiconductor memory device comprising:
a controller configured to generate a signal that controls an operation timing of the SRAM in synchronization with a basic clock signal, wherein:
the controller includes a clock generator that generates a first clock signal having a clock width that rises in synchronization with the basic clock signal and falls in accordance with a first timing control signal that is generated from the basic clock signal and passes through a delay path using the first bitline; and
the delay path includes:
a delay circuit that inputs the first timing signal generated in synchronization with the basic clock signal; and
a signal line that transmits the first timing control signal output from the delay circuit to the clock generator, using the first bitline included in each of two or more cell array blocks constituting the SRAM.

6. The semiconductor memory device of claim 5, wherein the clock generator is configured to generate the first clock signal having a clock width that determines a timing from starting of an operation of the SRAM in synchronization with a basic clock signal to ending of an operation by the first bitline.

7. The semiconductor memory device of claim 5, wherein the clock generator is configured to generate a second clock signal that rises in synchronization with a basic clock signal, the second clock signal to control a timing of a signal in a state in which the first bitline and the second bitline are connected.

8. The semiconductor memory device of claim 7, wherein the clock generator is configured to generate the second clock signal having a clock width that determines a timing from starting of an operation of the SRAM to ending of charge-sharing in a state in which the first bitline and the second bitline are connected.

9. The semiconductor memory device of claim 7, wherein the clock generator is configured to generate the second clock signal having the clock width that rises in synchronization with a basic clock signal and falls in accordance with a second timing control signal that passes through a delay path by a bitline corresponding to the second bitline.

10. The semiconductor memory device of claim 5, wherein the controller is configured to generate a control signal to connect the first bitline and the second bitline in synchronization with the first clock signal corresponding to a timing from starting of an operation of the SRAM to ending of an operation by the first bitline.

11. The semiconductor memory device of claim 8, wherein the controller is configured to generate a control signal to end the charging-sharing that is generated by connection between the first bitline and the second bitline, in synchronization with the second clock signal.

12. The semiconductor memory device of claim 8, wherein the controller is configured to generate a control signal that cuts off connection between the first bitline and the second bitline, in synchronization with the second clock signal, at a timing when the charge-sharing ends.

13. The semiconductor memory device of claim 8, wherein the controller is configured to generate a control signal that controls an operation timing from starting of a data read operation of the SRAM to ending of a change in voltage level of the first bitline in accordance with data, in synchronization with the first clock signal.

14. The semiconductor memory device of claim 13, wherein the controller is configured to, after the change in the voltage level ends, generate a control signal that controls an operation timing from when the charge-sharing is generated by connecting the first bitline and the second bitline to when the charging share is ended in synchronization with the second clock signal.

15. A semiconductor memory device that is applied to a static random access memory that is applied to a static random access memory (SRAM) with a hierarchical bitline structure including a first bitline and a second bitline, the semiconductor memory device comprising:
a controller configured to generate a signal that controls an operation timing of the SRAM in synchronization with a basic clock signal, wherein:
the controller includes a clock generator that generates:
a first clock signal having a clock width that determines a timing from starting of an operation of the SRAM in synchronization with the basic clock signal to ending of an operation using the first bitline; and
a second clock signal having a clock width that determines a timing from starting of an operation of the SRAM to ending of charge-sharing in a state in which the first bitline and the second bitline are connected.
